(19) United States
(12) Patent Application Publication
(10) Pub. No.: US 2003/0148030 A1
(43) Pub. Date: Aug. 7, 2003

(54) Barrier coatings for elastomeric materials

(76) Inventors: Paul M. Vernon JR., Chapel Hill, NC (US); Vinay Sakhrani, Raleigh, NC (US); Jerome J. Cuomo, Cary, NC (US)

Correspondence Address: MYERS BIGEL SIBLEY & SAJOVEC, PO BOX 37428, RALEIGH, NC, 27627, US

(21) Appl. No.: 10/167,122

(22) Filed: Jun. 11, 2002

Related U.S. Application Data
(60) Provisional application No. 60/297,676, filed on Jun. 12, 2001.

(51) Int. Cl. B32B 1/08; C23C 16/00

(52) U.S. Cl. 427/255.28; 428/36.91; 427/569

(57) ABSTRACT

An article of manufacture includes an elastomeric substrate and a plasma deposited polymeric coating on a portion of the elastomeric substrate. The polymeric coating can include a crosslinked amorphous polymer represented by a formula selected from the group consisting of:

(1) M¹ₓC_{y}H_{z}OₐN_{b}

wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating composition, except that M¹ and H may not be exclusively present; and

(2) M²_{c}C_{d}HₑO_{f}N_{g}

wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating composition, except that M² and H may not be exclusively present.

### RELATED APPLICATION

This application claims the benefit of U.S. Provisional Patent Application No. 60/297,676 filed on Jun. 12, 2001.

### FIELD OF THE INVENTION

The invention generally relates to polymeric coatings and methods of using the same.

### BACKGROUND OF THE INVENTION

Elastomers and rubbers are typically composed of long tangled chain-like molecules that uncoil and recoil under a load. This internal flexibility makes these materials flexible and highly elastic. These properties have made elastomeric materials extremely useful in a number of applications. The majority of the elastomers and rubber compounds produced worldwide are typically used in the manufacture of automobile tires, while the remainder of the materials are, for the most part, employed in consumer products such as shoes, clothing, furniture, and toys and mechanical parts such as mountings, belts, hoses, tubing, and seals such gaskets, O-rings, and stoppers. To optimize and customize materials for these various applications, elastomers and rubbers are usually compounded with processing aids and softeners, such as oils and plasticizers, vulcanizing agents and accelerators, fillers such as talc, and silica, colors such as carbon black and titania, and antioxidants, lubricants, and miscellaneous other ingredients. However, these additives can also become contaminants in some sensitive applications because of the tendency of these additives to outgas or be extracted from the rubber. For example, oil, or another volatile ingredient can outgas from vacuum O-ring seals depositing a film on sensitive electronic or optical surfaces or contaminating sensitive processes. Water vapor, oxygen and other gases are typically permeable through elastomers, limiting the vacuum levels that can be achieved with rubber O-rings requiring the use of expensive metal seals. Certain additives and rubber ingredients may be considered contaminates in food service and drinking water contact applications. Medical device seal applications, applications for implantable devices, and pharmaceutical closure stoppers and syringe plunger stoppers that may come in contact with pharmaceuticals must be in compliance with U.S. Food and Drug Administration (FDA) regulations. Some pharmaceuticals are potentially sensitive to common curing agents such as zinc or other heavy metals that are extractable from the rubber stopper.

Elastomers are typically known to have high friction characteristics, partially due to their elasticity. The “stick-slip” phenomena of an elastomer sliding on a substrate is believed to be due to the elastic nature of the elastomer. Under static frictional loading, the surface of the elastomer against a substrate will usually stretch until the static friction is overcome, the elastomer surface then breaks free or “slips”, rebounds to it's original shape, catches the substrate and “sticks” again. Examples of this phenomena are the stutter of automobile windshield blades or a squeegee against a dry windshield, and the stutter of a medical syringe pump. The high friction properties of elastomers has found uses in applications such as automobile tires, handle grips, and floor coverings. However, high friction has been a problem in other elastomer applications such as dynamic O-ring seals, pharmaceutical closure stoppers, and syringe plungers. It would be especially desirable for a lubricant to be employed in these applications in order for these devices to function properly.

Silicone oil, and in particular polydimethyl siloxane fluid, has long been used as a lubricant for elastomeric articles such as pharmaceutical stoppers, syringes, and valve seals. The silicone oil, however, is believed to be a residual contaminant particularly, for example, in drug delivery systems involving both injectable packaged drugs and syringes. Because of the possible uncertainty with respect to potential toxicity and regulatory issues relating to the use of silicone oil, there is currently an industry wide interest in finding an alternative to this material as a lubricant for medical and biological applications.

Numerous attempts have been made at developing alternatives to silicone oil. For example, a polymerized silicone coating for stoppers has been developed which employs UV radiation to crosslink a mixture of silicones on the surface of the elastomeric article. Although this technique is capable of reducing the number of silicone particles generated and potentially results in sufficient lubricity, the coating nonetheless still contains silicone oil.

Another attempt has focused on employing Parylene C® (i.e., chloro-para-xylene) as a coating. Notwithstanding the potential ability of this material to improve the drug compatibility of the rubber, this material is disadvantageous in that it may not be capable of simultaneously meeting both sealing and lubricity requirements for closures.

Composite rubber stoppers of butyl rubber tops and solid polytetrafluoroethylene (PTFE) have been developed in an attempt to address specific drug compatibility issues. Additionally, these rubber stoppers are usually undesirable from a cost standpoint. In certain embodiments, thin films of sheet PTFE are molded over rubber stoppers to form a laminate on one or both sides of the stopper. One side of the laminate usually requires a silicone coating on the top while two-sided laminates typically do not. The PTFE surface is capable of potentially providing good lubricity, and drug compatibility. Nonetheless, PTFE laminated films often display questionable flexibility, and have difficulty conforming to intricate shapes. These factors have served to limit the commercial success of these laminates, along with the high cost of manufacturing such.

There is a need in the art to provide a low friction barrier polymeric coating which provides adequate lubricity to the substrate (e.g., stopper) on which it is present and that minimizes potential adverse effects to various substrate properties such as, for example, sealing or coring. It would also be desirable to enhance the properties of the substrate (e.g., stopper or gasket) by minimizing the outgassing or elution of potential contaminants from the substrate, protect the substrate from adverse agents in the application environment (e.g. corrosive gases or fluids), minimize the permeability of the substrate to gases undesirable to the sealed environment (e.g. water vapor, oxygen) and/ or minimize loss of volatile components from a container (e.g. Freon, Halon).

### SUMMARY OF THE INVENTION

The present invention may address one or more of the problems in the prior art. In one aspect, the invention provides an article of manufacture including an amorphous polymeric coating composition. The polymeric coating composition can include a crosslinked amorphous polymer represented by a formula selected from the group consisting of:

(1) M¹ₓC_{y}H_{z}OₐN_{b}

wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of Mₓ¹ or C must be present and at least one of C, H, O, or N must be present in said polymeric coating composition, except that M¹ and H may not be exclusively present; and

(2) M²_{c}C_{d}HₑO_{f}N_{g}

wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating composition, except that M² and H may not be exclusively present.

In some embodiments, the total residue extracted by a volume of water contacted with the polymeric coating can be reduced by at least about 20% compared to the total residue extracted by an equivalent volume of water contacted with an elastomer substrate that is not coated with the polymeric coating under substantially the same conditions of pressure and temperature.

In certain embodiments, particle generation measured by the turbidity of a water sample contacted with the polymeric coating can be reduced by at least about 20% compared to the turbidity of a water sample contacted with an elastomeric substrate that is not coated with the polymeric coating under substantially the same conditions of pressure and temperature.

In further embodiments, the swelling of the elastomer substrate exposed to a solvent can be reduced by at least about 20% compared to the swelling of an elastomer substrate that is not coated with the polymeric exposed to the solvent under substantially the same conditions of pressure and temperature.

In certain embodiments, the elastomeric substrate has a coefficient of friction that is at least about 13% less than the coefficient of friction for an elastomeric substrate that is not coated with the polymeric coating.

Examples of suitable substrates are set forth in detail herein.

In another aspect, the invention provides a method of forming a crosslinked amorphous polymer. The method comprises exposing a composition comprising at least one metal organic precursor to an energy source to form a energized precursor, promoting the energized precursor into an excited state to produce ionic materials, and depositing the ionized materials on a substrate such that the ionized materials form the crosslinked amorphous polymer having the formula described herein.

These and other aspects and advantages of the invention will be described in detail.

### BRIEF DESCRIPTION OF THE DRAWINGS

FIG. 1 illustrates a comparison of the sliding characteristics for various stopper coatings.

FIG. 2 is a graph of the results of a sliding angle test.

FIG. 3 is a graph of the results of a coefficient of friction test.

FIG. 4 is the chemical structure of Tetramethyl Silane (TMS).

FIG. 5 is the chemical structure of Tetra Isopropyl Titanate (TIPT).

FIG. 6 is a 3-D model graph of Bias (-V) and TIPT flow (sccm) vs. thickness (Å).

FIG. 7 is a 3-D graph of Pressure (mTorr) and Bias (-V) vs. thickness (Å).

FIG. 8 is a 3-D graph of Pressure (mTorr) and Bias (-V) vs. Sliding Angle (°) on glass.

FIG. 9 is a 3-D graph of effects of Pressure (mTorr) and Bias (-V) on Turbidity (ntu) of water extract.

FIG. 10 is a graphical representation of an optimized desirability function for a screening experiment illustrating a graph of the desirability function vs. bias (-V) and pressure (mTorr).

FIG. 11 is a Box-Whisker Plot Comparing the Sliding Angle on Stainless Steel for TF22 Coated Stoppers and Controls.

FIG. 12 is a Box-Whisker Plot Comparing the Sliding Angle on Glass for TF22 Coated Stoppers and Controls.

FIG. 13 is a graph comparison of the effect of titanium-carbon plasma polymer coatings on turbidity and total extractables.

FIG. 14 is an EDS spectrum of an uncoated exemplary stopper.

FIG. 15 is an EDS spectrum of the exemplary stopper from FIG. 14 coated with titanium-carbon plasma polymer.

FIG. 16 is a schematic drawing of embodiments of a drug delivery device having a stopper in accordance with the invention.

FIGS. 17A-C are schematic drawings of embodiments of a drug vial and a stopper for storing medicament in accordance with the invention.

FIG. 18 is a schematic drawing of embodiments of a vacuum sealing assembly in accordance with the invention.

FIG. 19A-B are schematic drawings of embodiments of a drug delivery device, such as an inhaler, having a sealing member in accordance with the invention.

### DETAILED DESCRIPTION OF THE PREFERRED EMBODIMENTS

The present invention now will be described more fully hereinafter with reference to the accompanying specification and examples, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In one aspect, the invention comprises a polymeric coating composition. The composition comprises a crosslinked amorphous polymer represented by a formula selected from the group consisting of:

(1) M¹ₓC_{y}H_{z}OₐN_{b}

wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating composition, except that M¹ and H may not be exclusively present; and

(2) M²_{c}C_{d}HₑO_{f}N_{g}

wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating composition, except that M² and H may not be exclusively present. The polymer may be crosslinked three-dimensionally.

The polymer may reduce extraction of leachable elastomer components by solvents, reduce outgassing of volatile elastomer components, reduce swelling by solutions, oil, water, or other solvents, reduce diffusion of gases and water vapor, and/or reduce the coefficient of friction of the elastomeric substrate.

Preferably, the coating composition contains a metal, M¹ or M². However, various possible element combinations, without limitation, to be encompassed by the invention are as follows:

M¹ (or M²)—O;

M¹ (or M²)—N;

M¹ (or M²)—H—O;

M¹ (or M²)—H—N;

M¹ (or M²)—C—H—O;

M¹ (or M²)—C—H—N;

M¹ (or M²)—C—H—O—N;

M¹ (or M²)—C;

M¹ (or M²)—C—H;

C—H—N; and

C—H

As set forth above, the polymeric coating is present in the form of an amorphous polymer. For the purposes of the invention, the term “amorphous” refers to the polymer being non-crystalline. The coating composition is highly crosslinked, as evidenced by a reduced or lack of solubility and of swellability when exposed to solvents.

In various embodiments, the polymeric composition may include a number of specific elements. For example, in one embodiment, the polymeric composition may include either of M¹ or M² being titanium.

In one preferred embodiment, the polymeric composition may be essentially free of silicones (e.g., siloxane fluids or polymers). For the purposes of the invention, the term “essentially free” may be defined as the composition having equal to or less than 0.01 percent by weight of silicone oil.

In another aspect, the invention relates to an article of manufacture. The article of manufacture comprises the polymeric coating composition as defined herein and a substrate, with the polymeric coating composition being positioned on the substrate.

A number of substrates may be used in accordance with the invention. Typically, the substrate comprises an elastomeric material, rubber, or combinations thereof. Specific examples of articles of manufacture include, without limitation, seals such as, without limitation, a pharmaceutical closure (i.e., stopper) for a drug vial or a hypodermic syringe, an inhaler for delivering at least one pharmaceutical compound to a mammal in need of treatment, wherein the coating composition is typically present on the inhaler valve seal, valve stem seal, syringe plunger, an automobile gasket, a vacuum seal, and an o-ring. The coating may be present on all surfaces of the elastomeric material or a portion of the elastomeric material. Other articles of manufacture may be encompassed by the invention.

The polymeric coating composition may contact the substrate in various manners. Although not intending to be bound by theory, in one embodiment, the polymeric coating composition may be chemically (e.g., covalently) bonded to the substrate.

In one preferred embodiment, the crosslinked coating which is present on the substrate has a thickness ranging from about 50 Å to about 5 micrometers. In another preferred embodiment, the crosslinked coating which is present on the substrate has a thickness ranging from about 300 Å to about 5,000 Å. In yet another preferred embodiment, the crosslinked coating which is present on the substrate preferably has a density ranging from about 1.5 g/cc to about 2.2 or 2.5 g/cc.

In yet another preferred embodiment, the coatings of the invention have a sliding angle on an inclined plane ranging from about 10 degrees to about 25 degrees. A typical lubricity test that may be employed in evaluating the coatings is a comparative test that uses an inclined plane friction tester which gives repeatable values for static coefficient of friction. In one example of such a test, four test stoppers are inserted into an aluminum sled and the angle at which the sled begins to slide on a smooth metal plane is recorded. For flat planes, the coefficient of static friction is equal to the tangent of this angle. However, in this instance, due to the round shapes and raised features on the top of the stopper, only the angle of slide is recorded. In some embodiments, the total residue extracted by a volume of water contacted with the polymeric coating can be reduced by at least about 20% compared to the total residue extracted by an equivalent volume of water contacted with an elastomer substrate that is not coated with the polymeric coating under substantially the same conditions of pressure and temperature.

In other preferred embodiments, particle generation measured by the turbidity of a water sample contacted with the polymeric coating can be reduced by at least about 20% compared to the turbidity of a water sample contacted with an elastomeric substrate that is not coated with the polymeric coating under substantially the same conditions of pressure and temperature.

In still further preferred embodiments, the swelling of the elastomer substrate exposed to a solvent can be reduced by at least about 20% compared to the swelling of an elastomer substrate that is not coated with the polymeric exposed to the solvent under substantially the same conditions of pressure and temperature. Examples of solvents include oil, water, and other solutions, including pharmaceutical solutions.

In certain preferred embodiments, the elastomeric substrate has a coefficient of friction that is at least about 13% less than the coefficient of friction for an elastomeric substrate that is not coated with the polymeric coating.

In various optional embodiments, additional layers may be present on the polymeric coating composition in the article of manufacture. For example, in one embodiment, a lubricious hydrophobic layer is present on the polymeric coating composition. An example of a lubricious hydrophobic layer is provided in co-pending Ser. No. 09/304,422, filed Apr. 30, 1999, the disclosure of which is incorporated herein by reference in its entirety. The hydrophobic organic lubricant used to form the lubricous layer can be a topical lubricant such as used to reduce wear of rigid articles. However, the term “lubricant” as used herein is intended to encompass materials that accomplish the intended result of forming a hydrophobic wear-resistant surface on the polymeric coating composition, whether or not those materials are conventionally employed as lubricants. Hydrophobic properties of the top-coat may have an additional beneficial effect of increasing the water barrier properties of the multiple layer coating by preventing or minimizing the adsorption of water on the surface of the coating. Fatty acids and fatty acid esters are excellent boundary lubricants. Esters such as tridecyl stearate, butyl stearate, butyl palmitate, stearic acid, and myristic acids are commonly used lubricants and can be used to carry out the present invention. Fluorocarbons (i.e., fluoropolymers) such as perfluoropolyethers (PFPEs) may also be employed.

Examples of suitable fluorocarbons include, but are not limited to, fluoropolyethers, fluoroacrylates, fluoroolefins, fluorostyrenes, fluoroalkylene oxides (e.g., perfluoropropylene oxide, perfluorocyclohexene oxide), fluorinated vinyl alkyl ethers and the copolymers thereof with suitable comonomers, wherein the comonomers are fluorinated or unfluorinated. Preferred are perfluorinated fluoropolymers (i.e., perfluoropolymers), with the term “perfluorinated” as used herein meaning that all or essentially all hydrogen atoms on the polymer are replaced with fluorine. Fluoropolyethers are preferred, and perfluoropolyethers are most preferred. Fluoropolyethers or perfluoropolyethers with one or two terminal hydroxy groups are particularly preferred.

The lubricant may be applied to or deposited on the article of manufacture by any suitable means, such as by contacting the article to an aqueous or nonaqueous fluid containing the lubricant (e.g., by dipping). Excess lubricant can subsequently be removed by air drying, blotting, etc.

In another aspect, the invention relates to a method of forming a crosslinked amorphous polymer. The method comprises exposing a composition comprising at least one metal organic precursor to an energy source to form a energized precursor, promoting the energized precursor into an excited state to produce ionized materials, and depositing the ionized materials on a substrate such that the ionized materials form the crosslinked amorphous polymer represented by a formula selected from the group consisting of:

(1) M¹ₓC_{y}H_{z}OₐN_{b}

wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28 , a ranges from 0 to 4, and b ranges from 0 to 4, subject to the proviso that at least one of M¹ or C must be present and at least one of C, H, O, or N must be present in said polymeric coating composition, except that M¹ and H may not be exclusively present; and

(2) M²_{c}C_{d}HₑO_{f}N_{g}

wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating composition, except that M² and H may not be exclusively present. The resulting polymer may be crosslinked three-dimensionally in the manner described herein.

The coating used in accordance with the invention can be deposited on a substrate using a variety of techniques, the selection of which is known to one skilled in the art. For the purposes of the invention, the coating is formed by a plasma polymerization technique, which is typically referred to as an atomic, non-molecular process. See e.g., H. Yasuda, Contemp. Top. Polym., 3, 103 (1979). In one embodiment, an atomic process is initiated by an energetic species in a plasma which breaks down the monomer(s) into atomic and molecular species, which recombine and dissociate repeatedly before forming a polymer. The crosslinked amorphous polymers of the invention are preferably plasma polymers which characteristically are distinct from organic polymers and inorganic polymers.

Plasma polymerization is substantially different from conventional polymerization methods, and is not truly a polymer forming process in the classical sense. In conventional chain and step growth polymerization processes, a polymer is formed by the repetition of the same reaction over and over again, thus, the final polymer product bears a simple stoichiometric relation to the starting monomers.

In contrast to such molecular processes, and not intending to be bound by theory, polymer formation in plasmas has been generally recognized as an atomic, non-molecular process. The atomic process is typically initiated by an energetic species in the plasma which breaks down the monomer into atomic and molecular species, which recombine and dissociate over and over again before forming a polymer. In this case the resulting polymer does not have a stoichiometric relationship to the original monomer.

Films produced by the plasma polymerization technique are characterized as being amorphous, highly crosslinked films with short segments between crosslinks, and whose chemical composition may not resemble that of the starting monomer. For the most part, plasma polymers characteristically fall in between organic polymers (with high long range molecular mobility) and inorganic materials (with little, if any, long range mobility) [A. M. Wrobel, and M. Kryszewski, Progr. Colloid. Polym. Sci., 85, 91 (1991), which is hereby incorporated by reference in its entirety]. X-ray diffraction studies have been used to show the complete absence of crystallinity in these films [H. Kobayashi, A. T. Bell, M. Shen, J. Applied Polymer Science, 18, 885 (1973), which is hereby incorporated by reference in its entirety], and the crosslinked nature of these films has been substantiated by the inability of conventional organic solvents to dissolve plasma polymer films. Infrared spectra of plasma polymers contain broad, overlapping bands which are indicative of their complex stoichiometry, high degree of crosslinking and amorphous nature. Exemplary deposition techniques include, without limitation, Plasma Enhanced Chemical Vapor Deposition (PECVD), Chemical Vapor Deposition (CVD), sputtering, evaporation, and other deposition techniques such as plating, dip-, flow-, spray-, or spin coating. In a preferred embodiment, the coating is formed out of a material using precursors such as, for example, organo silanes (e.g., tetramethylsilane, trimethylsilane, hexamethyl disilane), organo siloxanes (e.g., polysiloxanes such as hexamethyl disiloxane), organo silazanes (e.g., hexamethyl disilazane), hydrocarbons (e.g., methane, ethane, ethylene), silicon alkoxides (e.g., tetramethoxysilane), metalorganics, or metal alkoxides (e.g., titanium alkoxides such as titanium isopropoxide), reactive gases (e.g, oxygen and hydrogen) as well as combinations of any of the above. In another preferred embodiment, the coating is formed out of a material using precursors such as, for example silanes, siloxanes, silazanes,titanates, and mixures thereof.

In one embodiment, a PECVD process may be employed utilizing any of the above-mentioned precursors (typically in the form of feed gas) introduced with or without argon or other inert gas. The precursors may subsequently be energized into a plasma by direct current, radio frequency, microwave, enhanced plasmas or by hollow cathode magnetron energy sources. The energized precursor (with or without energized argon or other inert gas) is promoted into an excited state, and is broken down producing at least one of ionized fragments, free radicals, atoms, molecules, and mixtures thereof, in an excited state which bombard and reconstruct on a substrate to produce a coating described herein. Among other factors, the precursor and the process conditions are believed to influence the specific compositions and properties of the coatings. The plasma enhanced chemical vapor deposition (PECVD) is preferably carried out at a temperature ranging from about 25° C. to about 350° C. and a pressure ranging from about 1 mTorr to about 100 mTorr. However, it will be appreciated that other temperatures and pressures can be employed. In one embodiment, a typical plasma is produced in a glow discharge and is characterized by possessing an average electron energy of from about 1 to about 20 eV and electron densities of from about 1×10⁹ cm⁻³ to about 1×10¹² cm⁻³. Additionally, the plasma process typically possesses a lack of equilibrium between the electron temperature (Tₑ) and gas temperature (T_{gas}). Typically values for Tₑ/T_{gas} range from about 10 to about 10². It should be appreciated that other conditions can be employed. The absence of thermal equilibrium makes it possible to obtain a plasma in which the gas temperature may be near ambient, while the electrons are sufficiently energetic to cause the rupture of molecular bonds. This characteristic makes glow discharge plasmas well suited for the promotion of chemical reactions involving thermally sensitive materials.

In an electric plasma discharge, free electrons which are present in the deposition system, typically as a result of photo ionization, cosmic rays, static charge, etc. [R. J. Salawitch, S. C. Wofsy, and M. B. McElroy, Planet. Space Sci., 36, 213 (1988), which is hereby incorporated by reference in its entirety], gain energy from an applied electric field and lose this energy via collisions with neutral gas molecules. If these electrons have sufficient energy to ionize the neutral molecules, additional electrons and cationic species can be created. Both the original and newly created electrons can then be accelerated and create new electrons and cations. This process creates an avalanching ionization effect that is responsible for creating and sustaining the plasma.

When organic molecules are used to generate a plasma, a myriad of chemical reactions can occur. The transfer of energy to the molecules typically leads to the formation of a variety of new species including free radicals, molecular ions and molecular metastables. These products are chemically active and can serve as precursors to the formation of new stable compounds. This is the basis for the plasma polymerization process.

In another aspect, the invention provides a crosslinked amorphous polymer formed by a method comprising exposing a composition comprising at least one metal organic precursor to an energy source to form a energized precursor; promoting the energized precursor into an excited state to produce ionized materials; and depositing the ionized materials on a substrate such that the ionized materials form the crosslinked amorphous polymer represented by a formula selected from the group consisting of:

(1) M¹ₓC_{y}H_{z}OₐN_{b}

wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating composition, except that M¹ and H may not be exclusively present; and

(2) M²_{c} C_{d}HₑO_{f}N_{g}

wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating composition, except that M² and H may not be exclusively present. A polymer is thus formed which may be crosslinked three-dimensionally. The method of forming the polymer may encompass, without limitation, any of the embodiments set forth herein.

The invention will now be described in greater detail with respect to the examples. It should be understood that the examples are for the purposes of illustration, and in no way limit the invention that is described by the claims. The coating composition described herein may be applied to elastomeric substrates such as on the inhaler valve seal, valve stem seal, syringe plunger, an automobile gasket, a vacuum seal, and an o-ring. Certain examples may have specific application to the pharmaceutical industry. However, the invention that is described by the claims is not limited to pharmaceutical uses. Non-pharmaceutical embodiments of the invention include o-rings, gaskets, test tube or bottle stoppers, diaphragms, bellows, automotive window and door gaskets, wiper blades, fuel lines, tubing catheter tubes, and other elastomer devices.

Exemplary evaluation techniques used in the following examples include:

Lubricity

The lubricity test is a comparative test using an inclined plane friction tester commonly used in the pharmaceutical closure industry. For flat plates, the coefficient of static friction is equal to the tangent of this angle. However, due to the round shapes and raised features on the top of the stopper, only the angle of slide is recorded. Lubricity is an issue for the automated filling of vials and syringes. The stoppers must slide in stainless steel vibratory feeder bowls and ramps and must have a low insertion force into the glass vial. Therefore the sliding angle against stainless steel and glass plates was measured.

Sealability

Sealing tests followed the industry liquid dye test technique. Dye is sealed in ten glass vials using an aluminum seal cap and stopper. The vials are inverted in water and held at a vacuum of 5 Torr. Any visible leak of the dye into the water is a failure.

Barrier Properties

The barrier properties were evaluated by comparison of coated and uncoated controls. The tests followed the USP Physicochemical Tests for Elastomeric Closures, Section 381, USP XXIII, which is hereby incorporated by reference in its entirety. These tests are the industry standards and will allow data comparisons with competing coating technologies. The total extractables and turbidity tests were used to evaluate the barrier properties of the coating to leachable rubber components and particle generation, respectively.

Adhesion

The industry technique for testing of adhesion of coatings on elastomers and other polymers is to steam autoclave the samples under water. Any separation of the coating is considered a failure. Adherence is pass/fail based on an optical microscope inspection of flexed rubber or by an increase in the turbidity of total extractables over the control.

The following analytical techniques were used in developing the coating:

Surface morphology using Scanning Electron Microscopy.

Coating thickness measurement using Stylus Profilometry.

Coating chemistry by X-ray photoelectron Spectrography (XPS) and Electron dispersion Spectrography (EDS).

### EXAMPLE 1A

### Evaluation of Sliding Angle of Individual Coated Butyl Rubber Stoppers on an Inclined Plane

Various coatings on 20 mm vial stoppers were evaluated for their respective sliding angles against stainless steel.

The plasma polymer coated stoppers (E) were coated using RF powered PECVD techniques with processing parameters of TMS at a flow rate of 1.5 sccm, 50 sccm argon, 50 mT pressure, and −250 volt substrate bias. Stoppers F were coated in the slame batch as E, but have the addition of a bonded layer of dihydroxyl PFPE as described in Example 4.

| Coating | Designation |
|---|---|
| Uncoated | A |
| Silicone Oil | B |
| Parylene 300Å | C |
| Parylene 1000Å | D |
| Invention E (TMS) | E |
| Invention F (TMS + PFPE) | F |

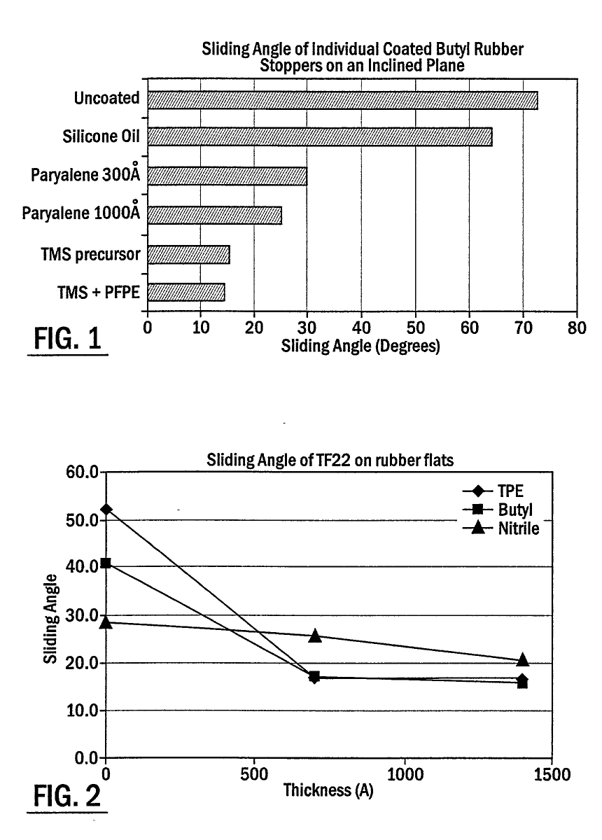

A through D represent comparative examples while coatings E and F represent embodiments encompassed by the present invention (e.g., C-Si coatings). Results of the evaluation are set forth in FIG. 1 and Table 1a.

TABLE 1a
Sliding Angle of Individual Stoppers

| TMS + PFPE | TMS precursor | Parylene 1000 Å | Parylene 300 Å | Silicone Oil | Uncoated |
|---|---|---|---|---|---|
| 14 | 15 | 25 | 30 | 64 | 72 |

As seen therein, the coatings of the invention largely display superior results relative to the prior art.

### EXAMPLE 1B

### Evaluation of Sliding Angle of Individual Coated Thermal Plastic Elastomer (TPE), Nitrile Rubber, and Butyl Rubber Substrate Sheets on an Inclined Plane

The low friction properties of the coating were evaluated on flat rubber substrates following ASTM D4516 Standard Test Methods for Measuring Static Friction of Coating Surfaces. In this test the friction coefficient of a stainless steel sled sliding against a coated rubber substrate is determined using the inclined plane technique. The sled is placed on the test substrate that is inclined at a constant rate until the sled begins to slide. The static friction is the tangent of the angle at which the sled begins to slip. Thermal plastic elastomer (TPE), nitrile rubber, and butyl rubber substrate sheets were coated with a plasma polymer of thicknesses of 700 and 1400 angstroms using plasma enhanced chemical vapor deposition (PECVD) techniques. The PECVD process parameters used were 1.5 sccm flow rate of tetraisopropyl titanate (TIPT), 50 sccm flow of argon, and 50 mTorr pressure and at substrate bias voltage of −250V. The static coefficient of friction of the rubber sheet was reduced compared to bare control rubber as shown in Table 1b and the sliding angles are shown in Table 1c. The coating reduced the static coefficient of friction compared to the control by 77% for TPE. For butyl rubber, the friction was reduced by 64 and 67% at 700A and 1400 A, respectively. The nitrile rubber had a higher hardness and smoother surface than the other examples, and as a result, showed improvements of 13% to 33% compared to the bare nitrile for the thicknesses studied.

TABLE 1b
Static Coefficient of Friction of Coated Flat Rubber

| | Thickness (A) | | | | |
|---|---|---|---|---|---|
| | 0 (Bare) | 700 | | 1400 | |
| | CoF | CoF | % change | CoF | % change |
| TPE | 1.3 | 0.3 | −77% | 0.3 | −77% |
| Butyl | 0.86 | 0.31 | −64% | 0.28 | −67% |
| Nitrile | 0.55 | 0.48 | −13% | 0.37 | −33% |

TABLE 1c
Sliding Angle for Coated Flat Rubber

| | Thickness (A) | | | | |
|---|---|---|---|---|---|
| | 0 (Bare) | | | | |
| | Sliding | | | | |
| | angle | 700 | | 1400 | |
| | (SA) | SA | % change | SA | % change |
| TPE | 52.3 | 16.7 | −68% | 16.7 | −68% |
| Butyl | 40.7 | 17.0 | −58% | 15.7 | −61% |
| Nitrile | 28.7 | 25.7 | −11% | 20.5 | −28% |

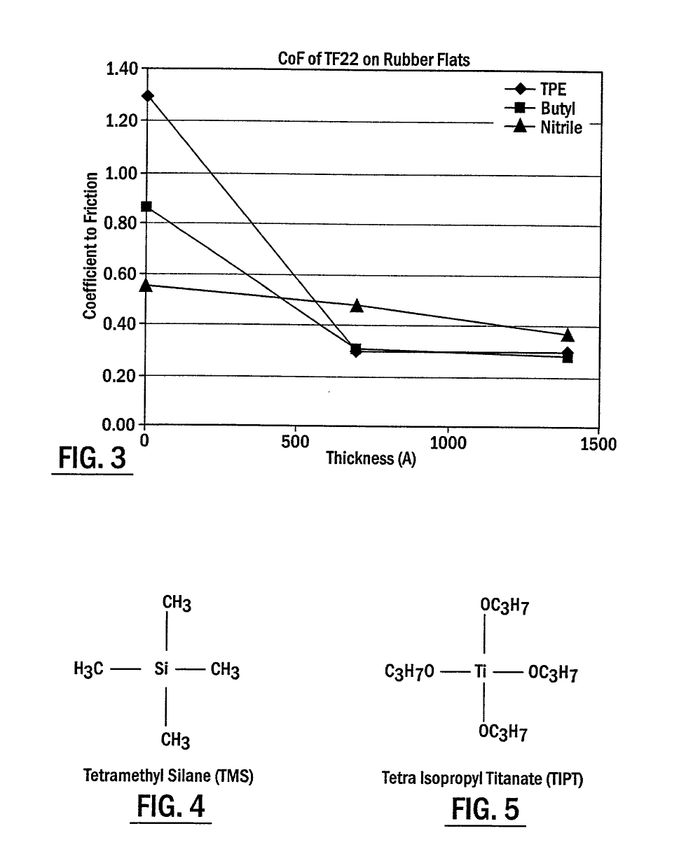

The results of the sliding angle tests are shown in FIG. 2. The results of the coefficient of friction tests are shown in FIG. 3.

### EXAMPLE 2

In this example the coated stoppers were evaluated by an independent laboratory and compared to bare control stoppers. All stoppers were 20 mm butyl rubber vial stoppers from the same manufacturing lot. The plasma polymer coatings were deposited using PECVD techniques described earlier. In this case the argon flow was 50 sccm, pressure 50 mT, and bias of-250V. The TMS flow rate was 1.5 sccm and the methane flow rate was 25 sccm. The coating thicknesses were about 1,500 Å. The sliding angle is determined by placing 4 stoppers in the bottom of a small sled weighing about 100 grams. The sliding angle is determined by measuring the angle at which the sled began to slide on a gradually inclined stainless steel plane.

TABLE 2
Coatings Evaluation Data

| | Sample ID and Composition | | |
|---|---|---|---|
| | Precursor | Precursor | Control |
| Tests | TMS | Methane | Butyl Rubber |
| Autoclave (Coating Change) | None | None | N/A |
| Friction Coeff. (Angle) | 47 | 62 | 66 |
| Seal (#leaks/10 vials) | 0 | 0 | 0 |

USP Physicochemical Tests <357>

| | | | |
|---|---|---|---|
| pH shift (pH) | −0.08 | −0.34 | −0.09 |
| Turbidity (NU) | 0.33 | 0.10 | 0.83 |
| Reducing Agents (mL of 0.01 | 0.00 | 0.00 | 0.00 |
| Iodine) | | | |
| Total Extractables | | | |
| (mg/100 mL) | 0.0 | 0.0 | 0.7 |

In this example, it appears that both plasma coatings exhibited good barrier properties, but the lower friction properties of the metal (Si) containing TMS-precursor coating may be preferred to carbon-hydrogen (DLC) coating of the methane-precursor coating.

### EXAMPLE 3a

### Barrier Properties

In this example, coating barrier properties are evaluated by comparison of coated and uncoated controls. The tests followed the USP Physicochemical Tests for Elastomeric Closures for Injections, Section 381, USP XXIII. These tests are the industry standards for evaluating closures and allow data comparisons with competing coating technologies. After cleaning, the stoppers were steam autoclaved under water for 2 hours at 121° C. following the procedures on Section<381>. The total extractables and turbidity tests were used to evaluate the barrier properties of the coating to leachable rubber components and particle generation, respectively. In this example, the butyl rubber stoppers were coated with a plasma polymer in accordance with the invention using PECVD techniques with process parameters of 1.5 sccm flow rate of TIPT, 50 sccm flow of Argon, 50 mTorr pressure, a coating thickness of 1,700 Angstroms, and at substrate bias voltages of −300V. The results are shown in Table 3.

TABLE 3

| Coatings on | Turbidity | | Extractables | |
|---|---|---|---|---|
| 20 mm butyl stoppers | (ntu) | % change | (mg) | % change |
| TIPT precusor Bias −300 V | 0.09 | −61% | 1.6 | −67% |
| Silicone Lubed Controls | 2.4 | 943% | 4 | −17% |
| Bare Controls | 0.23 | 0% | 4.8 | 0% |

This example illustrates one problem with the use of silicone oils as lubricants for packaging pharmaceutical liquids. As illustrated by the relatively high turbidity, but not wishing to be bound by theory, the silicone oil may form microscopic droplets in the liquid, which are detected as particles that scatter light.

### EXAMPLE 3b

### Barrier Properties

In this example butyl rubber 20 mm vial stoppers were coated with plasma polymer coatings. The PECVD process parameters used were 1.5 sccm flow rate of the precursor (TIPT or TMS), 50 sccm flow of argon, and 50 mTorr pressure and at substrate bias voltage of −250V. The properties of the coated stoppers were evaluated using the techniques described in Example 2 and 3A. The results are shown in Table 4.

TABLE 4

| | Thickness | Sliding Angle | | Turbidity | | Extractables | |
|---|---|---|---|---|---|---|---|
| Precursor | (A) | (deg) | % change | (ntu) | % change | (mg/100 cm2) | % change |
| TMS | 1240 | 36 | −44% | 16.7 | −70% | 6.6 | −52% |
| TMS | 1890 | 41.2 | −36% | 36.3 | −35% | 5 | −64% |
| TMS | 1700 | 31 | −52% | 24.3 | −56% | 8 | −42% |
| TMS | 2000 | 34.3 | −47% | 33.2 | −40% | 10.6 | −23% |
| TIPT | 1625 | 21.3 | −67% | 21.4 | −62% | 5.2 | −62% |
| TIPT | 2350 | 20.8 | −68% | 33.2 | −40% | 9.4 | −32% |
| Control | Bare | 64.6 | — | 55.7 | — | 13.8 | — |

### EXAMPLE 4

### Bonding of a Lubricious Top Coat

A lubricious coating can be bonded onto the plasma polymer coating to provide a bonded lubricant that experiences little, if any, migration. In this example the lubricious top coat is from the perfluoropolyoxyalkane group. The plasma polymer surface is activated with a burst of oxygen plasma which terminates the surface with reactive oxygen containing functional groups such as —COOH, —OH, —C=O, and the like. These functional groups facilitate the bonding (grafting) of the top layer. In this example, this grafted top layer is deposited by dip coating, although other techniques can be employed. The top layer is long chain, difunctional perfluoropolyether (PFPE). The active coating compound is a perfluorinated aliphatic fluorocarbon molecule with a general molecular structure as follows:

FG-CH₂CF₂O-(CF₂-CF₂—O)_{X}-(CF₂—O)_{y}—CF₂CH₂—FG

wherein FG is a functional group. The preferred compound contains a difunctional hydroxyl (—OH) group. The hydroxyl bonding group is the primary bonding sites, but there may be hydrogen bonding at the ether linkages.

The reactivity and the lubricity properties of the fluorocarbon molecule can be controlled by the following:

The functional group present on the fluorocarbon molecule

The degree of functionality (monofunctional or difunctional)

The molecular weight of the fluorocarbon molecule

Butyl rubber stoppers were coated under the following conditions: a TIPT flow of 1.5 sccm, an Argon flow 50 sccm, a pressure 50 mTorr, and a substrate bias of−250 V. These stoppers were immediately dip coated with a solution of dihydroxyl PFPE and cured for one hour at 100° C. The sliding angle was reduced by a statistically significant amount by the additional coating, from 32° to 22° for glass (An Analysis of Variation (“ANOVA”) one-way test is p=0.0059) and from 28° to 22° on stainless steel (ANOVA one way p=0.0002). (At a confidence interval of 95%, p values less than 0.05 indicate a statistically significant difference.)

### EXAMPLE 5

### Barrier to Gases and Water

The barrier properties of single layer coatings of highly crosslinked plasma polymers were tested for highly polar vapors (e.g., water vapor). FDA Food Grade nitrile rubber sheet 1.5 mm. thick, was used as the substrate in this example. The precursor gas was TIPT at 1.5 sccm/Argon 50 sccm/50 mTorr chamber pressure/Substrate bias−250 V and a thickness of 1700A. The water vapor barrier properties of the coating were tested using the ASTM F1249 method for water vapor transmission testing. Such tests may be obtained from commercial testing facilities, for example, Mocon Testing Laboratories, Minneapolis, Minn. At 100% humidity and 23° C., the average water transmission rate (gm/100in2*day) was 0.364 for bare nitrile rubber and 0.288 for the titanium-carbon plasma polymer coated sheet. The coating reduced the water vapor transmission rate of the nitrile rubber substrate by 21%.

### EXAMPLE 6

### Barrier to Oils

A TMS based plasma polymer was deposited onto nitrile rubber O-rings used in oil sealing applications such as down rigger oil drilling operations. The polar additives used to obtain the appropriate lubricating properties of the drill head lubricant would swell the bare O-ring by 5.06 percent resulting in seal failure over time. The O-rings which was coated with the plasma polymer based on the TMS precursor of the invention resulted in a volume swelling of only 0.48 percent thus extending the life of the O-ring material. The coating applied for this application was a double layer coating as described in Example 4 with a thickness of 1 micron.

Substrate: Nitrile Rubber ‘O’ ring

Application: Dynamic seal for oil chamber of Drilling Tool

Coating A: TMS plasma deposition

Parameters:

| | |
|---|---|
| 1. Precursor: | Tetramethyl silane (1.5 sccm) and Argon (50 sccm) |
| 2. Substrate Bias: | −250 volts |
| 3. Pressure: | 50 mT |
| 4. Thickness: | 1000 nm (1 micron) |

Coating B: Dihydroxy PFPE in fluorinated-solvent

Application: Dip Coating and post cure at 115 deg C for 60 minutes

| | |
|---|---|
| Test 1: | Sample was tested for change in volume (swelling) by |
| | immersion in the hydrocarbon lubricating oil. |
| Test 2: | Sample was tested in the actual equipment with probes |
| | mounted for measurement of temperature rise and torque. |

Results:

Table 5 shows a reduction of 90 percentage in swelling of the O-ring. The reduced swelling indicates improved barrier properties of the O-ring to polar additives in the oil, which are added to improve the performance of the lubricant.

Since the O-ring is used as a dynamic seal, the rise in temperature is a direct correlation to the amount of friction between the metal rod and the inside diameter of the O-ring. The coated O-ring shows a reduction of 60% in temperature rise at steady state (10 hours) indicating improved friction properties. The resulting torque in inch-pounds also has a direct relation to the coefficient of friction. The coated O-ring shows a reduction of 57% in friction and resulting torque when compared to the bare O-ring.

TABLE 5
‘O’ rings as Dynamic Seals, test results

| | Volume | | | | | | Torque |
|---|---|---|---|---|---|---|---|
| | Swell | Temperature in Fahrenheit | | | | | Inch-lb |
| | 18 hr | 0.1 hr | 0.2 hr | 0.5 hr | 1 hr | 10 hr | 10 hr |
| Bare Nitrile | 5% | 127.5 | 140 | 152.5 | 155 | 290 | 17.5 |
| Rubber O-ring | | | | | | | |
| Coating on Nitrile | 0.48% | 92.5 | 100 | 105 | 110 | 115 | 7.5 |
| O-ring | | | | | | | |
| % change | −90% | −27% | −29% | −31% | −29% | −60% | −57% |

### EXAMPLE 7

### Composition of Coating

In this example, the surface composition and chemistry of samples of thin films on elastomeric substrates were determined using electron spectroscopy for chemical analysis (ESCA). The ESCA data were acquired from an analyzed area having a diameter of ca. 1 mm using a monochromatic Al Ka x-ray source. Low energy resolution survey scans were obtained from each sample to determine what elements were present. The atomic concentrations of these elements were determined from higher energy resolution multiplex scans. The results are shown in Table 6.

TABLE 6

| | Material | Substrate | Pressure | atomic percent | | | |
|---|---|---|---|---|---|---|---|
| Precursor | Type | Bias (−V) | (mT) | [C] | [O] | [Ti] | [Si] |
| TIPT | TPE | 300 | 50 | 90.9 | 6.4 | 2.7 | ND |
| TIPT | TPE | 300 | 70 | 95 | 3.7 | 1.2 | ND |
| TIPT | Nitrile | 250 | 50 | 64.2 | 27.1 | 8.7 | ND |
| TMS | BUNA-N | 250 | 50 | 83.5 | 9.3 | ND | 7.1 |

ND—Not Detected.

The ESCA data show the presence of varying concentrations of carbon (C), oxygen (O), titanium (Ti), and silicon (Si). The TIPT samples all show the presence of titanium dioxide (TiO2). This assignment is based on the binding energy for the Ti 2p3 transition line. The TMS sample shows the presence of silicon instead of titanium. The silicon binding energy is 101.5 eV, which indicates the presence of C—O—Si type species. The source of the oxygen present in the TMS sample is as a contaminant from background gas and residual water in the vacuum system.

Example 8

### Flexible, Low Friction Titanium—Carbon Plasma Polymer Coating for Elastomers

Materials and Equipment

The test articles were 20-mm butyl rubber stoppers. Typical chemistry and properties of these elastomers as reported by the suppliers is shown in Table 7.

TABLE 7
Typical Properties of Test Materials

| Supplier | Supplier B | Supplier A |
|---|---|---|
| Device | 20 mm Stopper | 20 mm Stopper |
| Elastomer | Halobutyl blend | Butyl blend |
| Color | Blue | Gray |
| Hardness Duro A | 50 | 40 |
| Specific gravity | 1.23 | 1.15 |
| Ash | 34.30% | 29.5 |
| USP <381> | | |
| pH change | 0.04 | 0.6 |
| Turbidity (ntu) | 6.76 | 10 |
| Reducing agents | 0.00 | 0.00 |

The deposition system used for this study is a Plasma Enhanced Chemical Vapor Deposition (PECVD) system. The PECVD system must be tuned according to techniques known to those of ordinary skill in the art. It should be appreciated that tuning of the PECVD system for a desired result may depend on the peculiarities of the PECVD system used, and therefore, the particular settings (e.g., pressures, bias voltages, etc) described herein are for illustrative purposes and may be system dependent. The system uses a water cooled capacitively coupled substrate plate powered by a radio frequency (rf) power supply (RFI 100) through a tunable matching network. The system is pumped with a turbo pumping package and MKS pressure controller. The titanium precursor source was tetra isopropyl titanate (TIPT) in liquid isopropanol (Tyzor TPT titanate from DuPont). A MKS liquid vapor flow controller supplied the liquid precursor to the chamber via an internal gas distribution ring.

Development of Low Friction Barrier Coating

Coatings deposited with tetramethyl silane (TMS) have been formed and evaluated. The TMS plasma coating is an amorphous densely packed matrix structure. The resulting surface is dry and lubricious with excellent barrier properties resulting due to the absence of grain boundaries. However, the element Si could be detected in the coating. The TMS plasma coating may not be considered acceptable for use in humans because of public perceptions of silicone used in implantable devices. The relevant consumers may not make the distinction between a silicone containing device and elemental Si containing coating.

A new flexible and lubricious barrier coating free of silicone and elemental silicon was evaluated. A preferred precursor is Tetra Isopropyl Titanate (TIPT). The resulting coating includes a matrix structure and titanium as a dopant.

The chemical structure of Tetramethyl Silane (TMS) is shown in FIG. 4, and the chemical structure of Tetra Isopropyl Titanate (TIPT) is shown in FIG. 5.

Since TIPT is a large molecule, it is used with an inert carrier gas like argon. The argon increases the degree of ionization of TIPT due to increased ionic bombardment caused by Argon ions and metastables created in the plasma environment. This task involved the optimization of the following plasma parameters:

Precursor gas composition (Argon/TIPT gas ratio)

Operating pressure in the reaction chamber.

The negative bias created on the driving electrode, which is related to the power of the excitation signal.

Deposition time.

A designed experiment was used to screen and identify the most important parameters. The above parameters were investigated with deposition time held constant. Preliminary test runs determined that 20 minutes would provide a measurable coating at the lowest deposition rate conditions. Each run included 40 stoppers coated on both sides with glass slides for thickness measurements and flat butyl and nitrile rubber sheet samples for contact angle and surface measurements. Table 8 illustrates the test parameters for screening 3 factors in 2 level factorial design.

TABLE 8

| Sample | Std | Bias | Press | TIPT | Argon | Time |
|---|---|---|---|---|---|---|
| ID | Run # | Volts | mTorr | sccm | sccm | min |
| 71301.2 | 1 | −200 | 40 | 2 | 50 | 20 |
| 71201.2 | 2 | −300 | 40 | 1 | 50 | 20 |
| 71101.2 | 3 | −200 | 60 | 1 | 50 | 20 |
| 71303.4 | 4 | −300 | 60 | 2 | 50 | 20 |

Analysis of Results

The test results of the designed experiment where analyzed using Design-Expert 5 software by Stat-Ease, Inc. Minneapolis, Minn.

TABLE 9
Results of the Designed Experiment

| n = 10 | | TIPT | | Sliding | | Turbidity | Total Extract |
|---|---|---|---|---|---|---|---|
| Bias | Press | flow | Thick | Glass | SS | water | water |
| (Volts) | (mTorr) | (sccm) | (A) | (degrees) | | (ntu) | (mg) |
| −200 | 40 | 2 | 1554 | 39 | 38 | 0.7 | 0.8 |
| −300 | 40 | 1 | 1023 | 54 | 46 | 1.0 | 0.2 |
| −200 | 60 | 1 | 875 | 46 | 43 | 0.6 | 0.8 |
| −300 | 60 | 2 | 2540 | 44 | 30 | 0.5 | 0.6 |

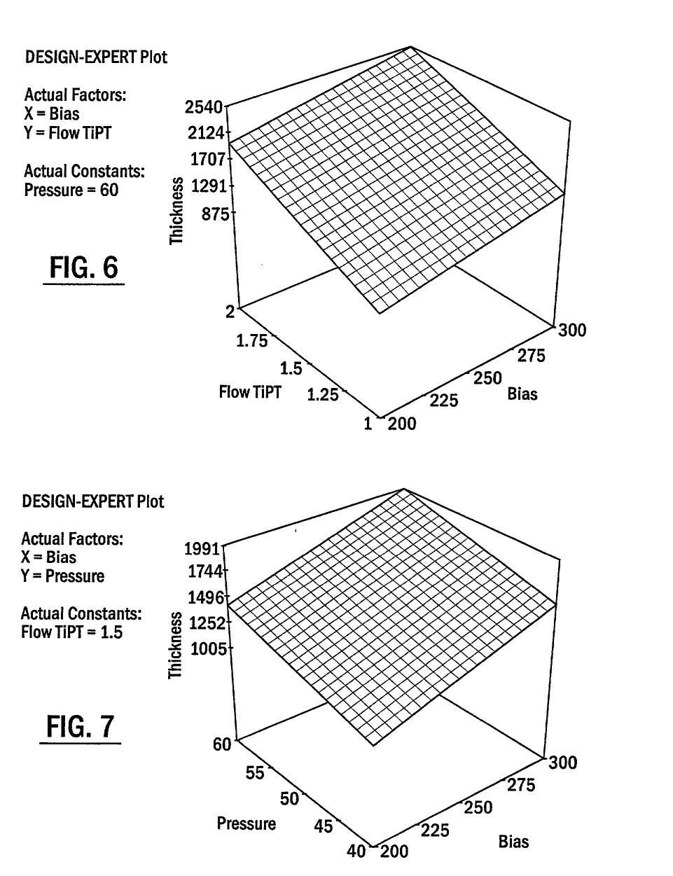

The thickness of the coating increased with increases in the substrate bias, TIPT flow rate, and chamber pressures. This relationship is illustrated in FIGS. 6 and 7. Increases in the flow, pressure, and bias result in higher concentrations of the reactive species in the plasma available for deposition and therefor increase the deposition rate. FIG. 6 is a 3-D model graph of Bias (-V) and TIPT flow (sccm) vs. thickness (Å). FIG. 7 is a 3-D model graph of Pressure (mTorr) and Bias (-V) vs. thickness (Å).

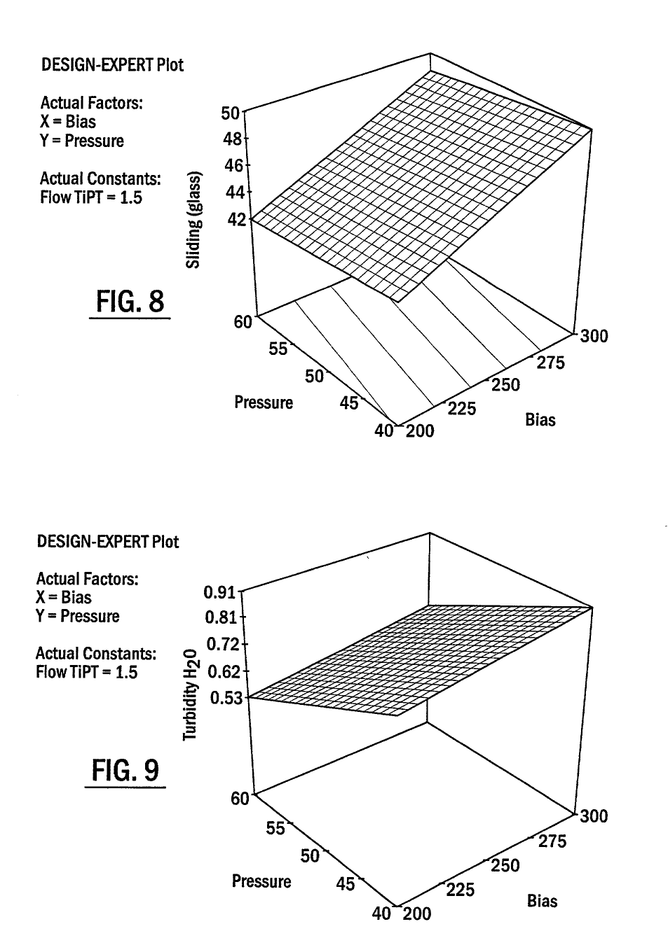

The sliding angle of the coated stoppers was measured for the coated stoppers on glass and stainless steel. In both cases the pressure did not appear to have a significant impact on the characteristics. The flow of TIPT was an important factor for both cases with the tendency for higher flow rates to produce a lower sliding angle. FIG. 8 is a 3-D graph of Pressure (mTorr) and Bias (-V) vs. Sliding Angle (°) on glass. For sliding on glass, a lower bias resulted in lower friction as shown in FIG. 8. The bias was less significant for sliding on stainless steel with the slightly the opposite effect: higher bias values slightly increased the predicted sliding angle on stainless steel.

FIG. 9 is a 3-D model of effects of Pressure (mTorr) and Bias (-V) on Turbidity (ntu) of water extract. The turbidity of the water extracts was lowest for high pressure and low bias factors as shown in FIG. 9. TIPT flow appeared to have little effect on turbidity.

The total extactables is a measurement of the weight of the residue after evaporating the solvent used for extraction in units of mg/100 ml. The processing factors that resulted in the lowest total extractables were a high bias, low TIPT flow rate and low pressure.

Optimization

One goal of the coating development is to produce coating that is low friction while still producing a good barrier to reduce the amount of particles and additives from reaching the drug. It may also be desirable to achieve these ends with the thinnest possible coating to minimize processing time and manufacturing costs. It becomes apparent in reviewing the results that there may be a conflict in achieving all of these goals at the same parameter settings. Table 10 summarizes the assigned importance and setting of each factor in producing the desired results.

TABLE 10
Factor Settings to Obtain the Desired Responses

| | Desired Response | | | |
|---|---|---|---|---|
| | low friction | low friction | | |
| Factors | glass | stainless | low turbidity | low extract |
| Bias | low | neutral | high | low |
| Pressure | neutral | high | high | high |
| TIPT flow | high | high | neutral | low |

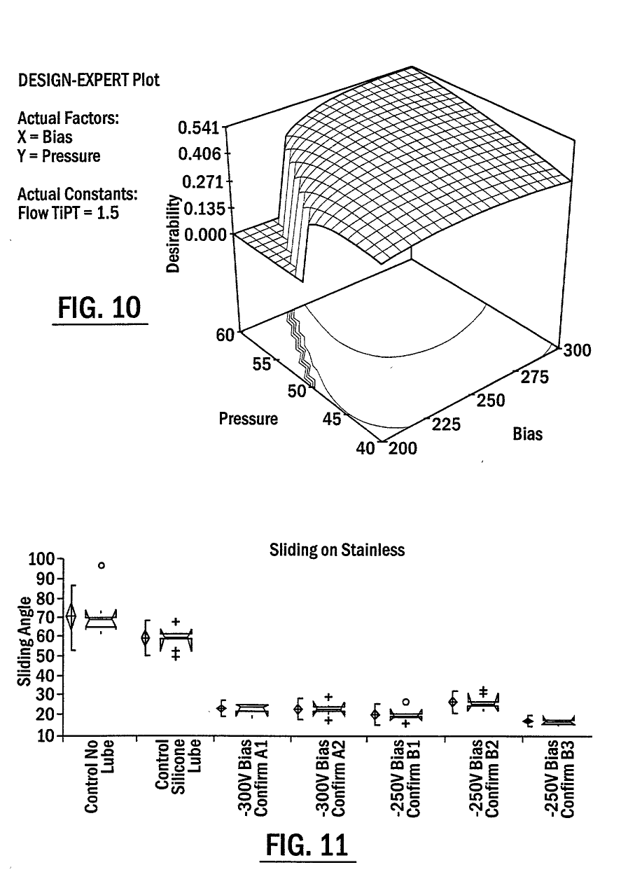

A simultaneous optimization of multiple responses can be calculated by assigning goals and limits to the response variables. For several responses, an objective function is constructed that combines all goals into one desirability function. The desirability function is set up where zero is outside the limits and 1 is the goal. The objective of the optimization search is to find a point that maximizes the desirability function. The desirability function at the conclusion of the optimization gives some idea how well the goals were met. FIG. 10 shows a graphical representation of an exemplary optimized desirability function for this screening experiment illustrating a graph of the desirabity function vs. bias (-V) and pressure (mTorr).

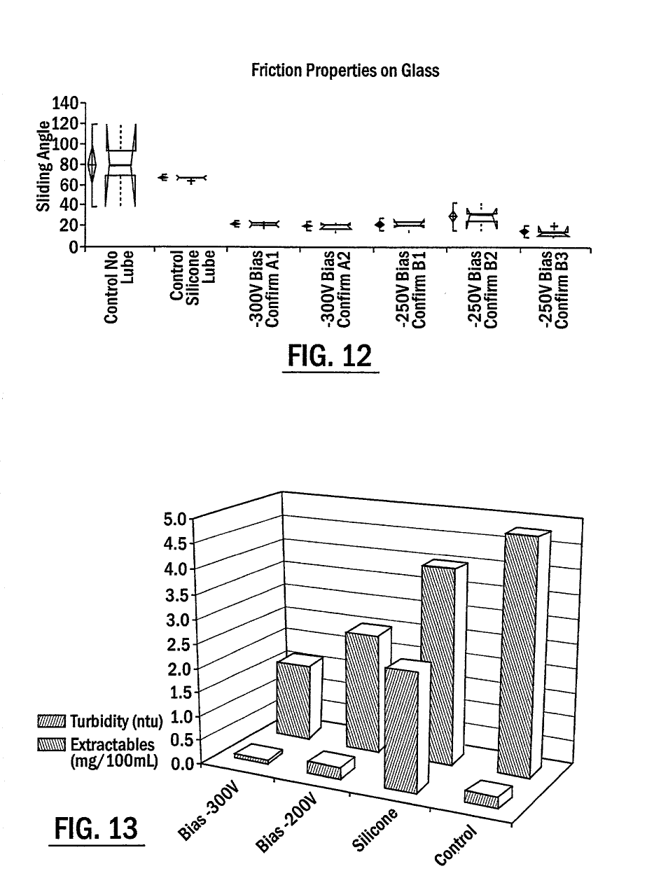

Based on this analysis, confirmation parameters were chosen near the center of the plateau on the response surface in FIG. 10. The confirmation runs were run with factor settings at 1.5 sccm TIPT, 50 mTorr pressure and-300V and-250V substrate bias. The resulting optimized process produced a low friction coating that reduced the extractable and particulate material released into purified water. The test data is shown in Table 11 and FIGS. 11 and 12. Table 12 illustrates the reduction in sliding angle of the tested stoppers.

TABLE 11
Results of Confirmation Run.

| Stoppers n = 10 | | | | | Sliding | | Turbidity | Extract | Sealing | |
|---|---|---|---|---|---|---|---|---|---|---|
| Sample | Bias | Press | TIPT | Thick | Glass | SS | water | water | dye leak | Adherence |
| ID | Volts | mTorr | sccm | A | degrees | | ntu | mg | pass/fail | pass/fail |
| A1 | −300 | 1.5 | 50 | 1256 | 23 | 20 | 0.09 | 1.6 | — | pass |
| A2 | −300 | 1.5 | 50 | 1637 | 21 | 24 | — | — | pass | pass |
| B1 | −250 | 1.5 | 50 | 1700 | 18 | 19 | 0.43 | 2 | — | pass |
| B2 | −250 | 1.5 | 50 | 1428 | 25 | 21 | 0 | 3 | pass | pass |
| B3 | −250 | 1.5 | 50 | 1775 | 32 | 28 | — | — | — | pass |

| | | | | | | |
|---|---|---|---|---|---|---|
| Bare Control | 99 | 75 | 0.23 | 4.8 | pass | n/a |
| Silicone coated Control | 67 | 68 | 2.4 | 4 | pass | n/a |

TABLE 12
Reduction in Friction (Sliding Angle) of Stoppers

| | | | | | Reduction in | |
|---|---|---|---|---|---|---|
| Stoppers n = 10 | | | Sliding Angle | | Friction | |
| Sample | Bias | Thick | Glass | Stainless | Glass | Stainless |
| ID | Volts | A | Degrees | | per cent | |
| TIPT -a1 | −300 | 1256 | 23 | 20 | 77% | 73% |
| TIPT -a2 | −300 | 1637 | 21 | 24 | 79% | 68% |
| TIPT -b1 | −250 | 1700 | 18 | 19 | 82% | 75% |
| TIPT -b2 | −250 | 1428 | 25 | 21 | 75% | 72% |

| | | | | |
|---|---|---|---|---|
| Silicone lubricated | 67 | 68 | 32% | 9% |
| Bare controls | 99 | 75 | 0% | 0% |

The confirmation runs test results for friction properties are shown in Table 13 and 14 and FIGS. 11 and 12.

Table 13 is a one way ANOVA analysis contrasting friction properties on stainless steel of silicone lubricated controls vs. titanium-carbon plasma polymer coating confirmation runs. This statistical data is shown graphically in box-whisker plot depicted in FIG. 11.

TABLE 13

| n | 58 | | | |
|---|---|---|---|---|
| Sliding Angle on Stainless | n | Mean | SD | SE |
| Control Silicone Lubricant | 9 | 59.4 | 5.4 | 1.80 |
| Confirm A1 | 10 | 23.4 | 2.5 | 0.78 |
| Confirm A2 | 10 | 23.8 | 3.3 | 1.04 |
| Confirm B1 | 10 | 21.4 | 3.1 | 0.99 |
| Confirm B2 | 10 | 28.1 | 3.6 | 1.14 |
| Confirm B3 | 9 | 19.1 | 1.6 | 0.54 |

| Source of variation | SSq | DF | MSq | F | p |
|---|---|---|---|---|---|
| Sliding Angle on Stainless | 10390.5 | 5 | 2078.1 | 177.03 | <0.0001 |
| Within cells | 610.4 | 52 | 11.7 | | |
| Total | 11000.9 | 57 | | | |

| | | Dunnett |
|---|---|---|
| Contrast | Difference | 95% CI |
| Confirm A1 v Control Silicone | −36.0 | −40.2 to −31.9 (significant) |
| Lube | | |
| Confirm A2 v Control Silicone | −35.6 | −39.8 to −31.5 (significant) |
| Lube | | |
| Confirm B1 v Control Silicone | −38.0 | −42.2 to −33.9 (significant) |
| Lube | | |
| Confirm B2 v Control Silicone | −31.3 | −35.5 to −27.2 (significant) |
| Lube | | |
| Confirm B3 v Control Silicone | −40.3 | −44.6 to −36.1 (significant) |
| Lube | | |

FIG. 12 is a box-whisker plot comparing the sliding angle on glass for a titanium-carbon plasma polymer coated stopper and controls. Table 14 is a one way ANOVA analysis contrasting friction properties on glass of a silicone lubricated control and a titanium-carbon plasma polymer coating confirmation run.

TABLE 14

| | | (cases excluded: |
|---|---|---|
| n | 58 | 1 due to missing values) |

| Sliding on Glass | n | Mean | SD | SE |
|---|---|---|---|---|
| Control Silicone Lube | 10 | 67.4 | 1.7 | 0.54 |
| Confirm A1 | 10 | 22.7 | 2.2 | 0.70 |
| Confirm A2 | 10 | 21.3 | 2.6 | 0.83 |
| Confirm B1 | 9 | 24.1 | 3.6 | 1.18 |
| Confirm B2 | 10 | 32.4 | 8.2 | 2.59 |
| Confirm B3 | 9 | 18.3 | 3.5 | 1.17 |

| Source of variation | SSq | DF | MSq | F | p |
|---|---|---|---|---|---|
| Control | 16761.8 | 5 | 3352.4 | 186.26 | <0.0001 |
| Within cells | 935.9 | 52 | 18.0 | | |
| Total | 17697.7 | 57 | | | |

| | | Dunnett |
|---|---|---|
| Contrast | Difference | 95% CI |
| Confirm A1 v Silicone Lube | −44.7 | −49.7 to −39.7 (significant) |
| Confirm A2 v Silicone Lube | −46.1 | −51.1 to −41.1 (significant) |
| Confirm B1 v Silicone Lube | −43.3 | −48.4 to −38.2 (significant) |
| Confirm B2 v Silicone Lube | −35.0 | −40.0 to −30.0 (significant) |
| Confirm B3 v Silicone Lube | −49.1 | −54.2 to −44.0 (significant) |

FIG. 13 illustrates a comparison of the effect of titanium-carbon plasma polymer coatings on turbidity and total extractables.

Conclusions

Using 20-mm closure stoppers as a model, a non-silicone low friction barrier coating was successfully developed. Titanium-carbon plasma polymer coated stoppers were demonstrated to have 68% lower sliding friction than silicone-coated stoppers. The barrier properties of the coating reduce turbidity compared to the silicone-coated stopper by 96% and reduced the total extractables leached from the rubber by 60%.

### EXAMPLE 9

### Surface Chemical Analysis

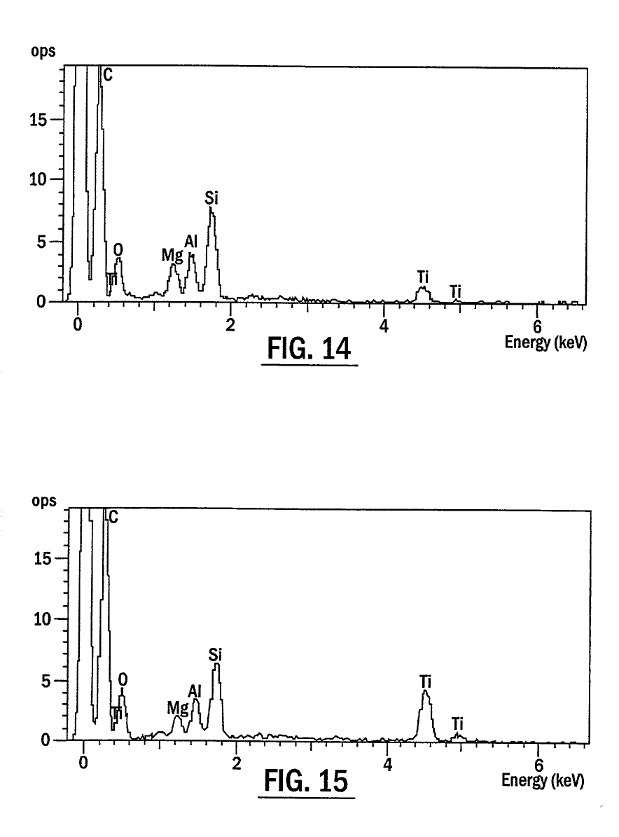

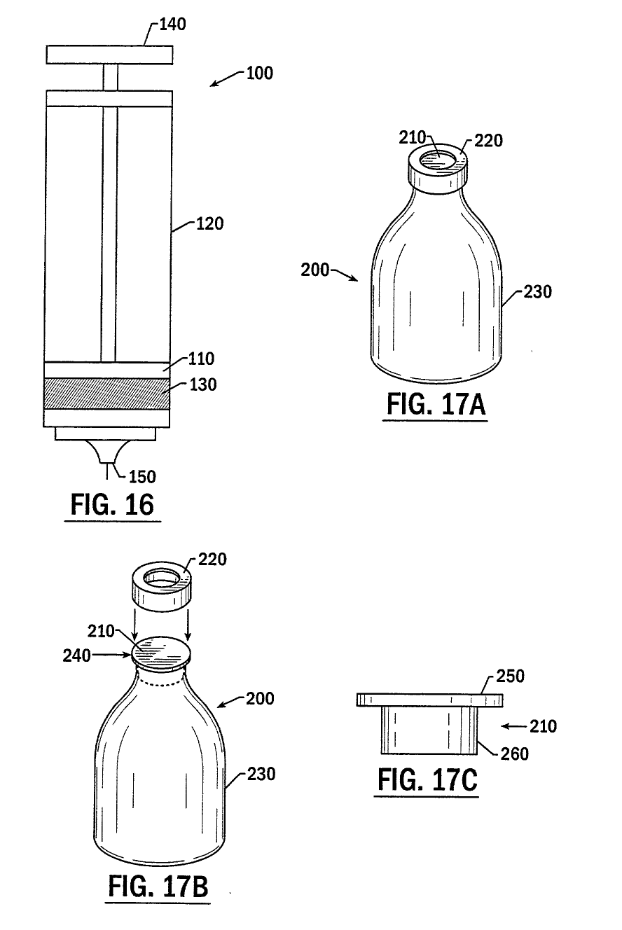

Coated and bare stoppers were evaluated with Hitachi environmental SEM with EDS capability. FIG. 14 is an EDS spectrum of bare butyl rubber stopper. The stopper is described by its manufacturer as a halobutyl rubber, but essentially no halogens were detected in the EDS spectrum shown in FIG. 14. The fillers used in the stopper are most likely talc and alumina, based on the presence of Mg, Al, and Si.

FIG. 15 is an EDS spectrum of a butyl rubber stopper coated with titanium-carbon plasma polymer. The EDS spectrum of a coated stopper is shown in FIG. 15 is very similar to the bare stopper in FIG. 14. The spectrum shown is for a 2540 Å thick coating, run #713034 of titanium-carbon plasma polymer on a Tompkins stopper. The EDS signal penetrates the coating and also detects the bulk material under the coating. The primary difference is an increase in the titanium signal and attenuation of the signal of filler material elements.

X-Ray Photoelectron Spectroscopy (XPS) is a surface analytical technique that penetrates only the top few atomic monolayers. XPS was used to analyze titanium-carbon plasma polymer coatings deposited on silicon wafer chips. Titanium, oxygen, and carbon were the only elements detected. Oxygen is present in the TIPT as well as the isopropanol carrier liquid. The titanium 2P1/2 and 2P3/2 peaks were a precise match for TiO2 titanium-oxygen bonding. Titanium-carbon bonding was not detectable in the film. Without wishing to be bound by theory, this may indicate that the titanium-carbon plasma polymer coating may be Ti—O bonded network in a carbon matrix.

### EXAMPLE 9

FIG. 17 is a schematic drawing of embodiments of a drug delivery device. In the example shown, the drug delivery device is a drug container such as a syringe 100 having a barrel 120 for containing a pharmaceutical substance 130. The syringe 100 includes a plunger 140 having a stopper 130 for forcing the pharmaceutical substance 130 through a blunt end 150. The blunt end 150 has an opening through which the substance within the barrel 120 can be expelled. The stopper 110 has an elastomeric substrate and a plasma deposited polymeric coating as defined herein on a portion or all of the elastomeric substrate. Other drug delivery and stopper configurations known to those of skill in the art may be used.

### EXAMPLE 10

FIGS. 17A and 17B are schematic drawings of embodiments of a drug vial 200 for storing medicament in accordance with the invention. The drug vial 200 includes a container 230 having an open end with a radial rim portion 240. A stopper 210 is inserted into the open end of the container 230. The stopper 210 is shown in greater detail in FIG. 17C. The stopper 210 includes a tubular portion 260 which can be inserted into the open end of the container 230 and a generally planar rim portion 250 which overlies the radial rim portion of the container 230. The stopper 110 has an elastomeric substrate and a plasma deposited polymeric coating as defined herein on a portion or all of the elastomeric substrate. Other stopper and vial arrangements known to those of ordinary skill in the art may be used.

### EXAMPLE 11

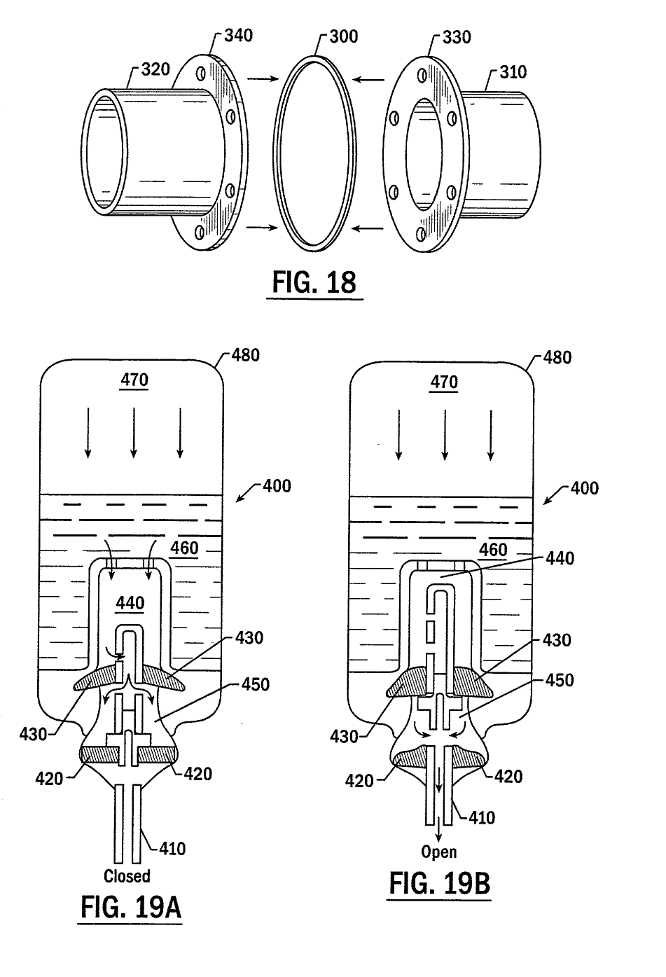

FIG. 18 is a schematic drawing of embodiments of a vacuum sealing assembly in accordance with the invention. The vacuum sealing assembly includes a first closure member 310 which has an opening defined by a rim 330. The second closure member 320 is sized to cover the opening defined by rim 330. A sealing member 300 can form a connection seal between the first closure member 310 and the second closure member 320. The sealing member 300 can be an O-ring or gasket. The sealing member 300 has an elastomeric substrate and a plasma deposited polymeric coating as defined herein on a portion or all of the elastomeric substrate. In addition, other vacuum sealing assemblies and sealing configurations known to those of ordinary skill in the art may be used.

### EXAMPLE 12

FIGS. 19A and 19B are exemplary schematic drawings of embodiments of a drug delivery device having a sealing member in accordance with the invention. The drug delivery device shown is an inhaler 400, and is depicted in a closed position in FIG. 20A and in an open position in FIG. 20B. The inhaler 400 includes a container 480 for a pharmaceutical substance 460 and a gas 470 that may be held at a pressure greater than atmospheric pressure. The inhaler 400 includes a valve 410 and one or more upper and lower seals, 430 and 420, respectively. The pharmaceutical substance 460 enters a first metered dose containment area 440. In a closed position shown in FIG. 20A, the pharmaceutical substance 460 is allowed to flow into a second metered dose containment area 450. In the open position shown in FIG. 20B, the pharmaceutical substance 460 in the second metered dose containment area 450 is allowed to exit through the valve 410. In the open position, the second metered dose containment area 450 is isolated from the first metered dose containment area 440 by upper seals 430. The upper and lower seals, 430 and 420, may include an elastomer substrate and a plasma deposed coating as defined herein on a portion or all of the elastomer substrate.

Other drug delivery device configurations known to those of ordinary skill in the art may be used. Such configurations may include stationary and dynamic sealing mechanisms including an elastomer substrate and a plasma deposed coating as defined herein on a portion or all of the elastomer substrate. A stationary seal is a seal that is not adjacent a movable part. A dynamic seal, such as upper and lower seals 430 and 420, is adjacent a movable part (e.g., the movable valve 410). One example of an alternative drug delivery system is disclosed in U.S. Pat. No. 5,836,299, which is hereby incorporated by reference in its entirety.

The invention is illustrated by reference to the above embodiments. It should be appreciated however that the invention is not limited to these embodiments but is instead defined by the claims that follow.

That which is claimed:

1. An article of manufacture comprising:
an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the total residue extracted by a volume of water contacted with the polymeric coating is reduced by at least about 20% compared to the total residue extracted by an equivalent volume of water contacted with an elastomeric substrate that is not coated with the polymeric coating under substantially the same conditions of pressure and temperature.

2. The article of manufacture of claim 1, wherein the polymeric coating provides at least one of reduced extraction of leachable elastomer components by solutions and solvents; reduced outgassing of volatile elastomer components; reduced swelling by oil, water, or other solvents; reduced diffusion of gases and water vapor; and a reduced coefficient of friction to the elastomeric substrate.

3. The article of manufacture of claim 1, wherein particle generation measured by the turbidity of a water sample contacted with the polymeric coating is reduced by at least about 20% compared to the turbidity of a water sample contacted with an elastomeric substrate that is not coated with the polymeric coating under substantially the same conditions of pressure and temperature.

4. The article of manufacture of claim 1, wherein the swelling of the elastomer substrate exposed to a solvent is reduced by at least about 20% compared to the swelling of an elastomeric substrate that is not coated with the polymeric coating exposed to the solvent under substantially the same conditions of pressure and temperature.

5. The article of manufacture of claim 1, wherein the elastomeric substrate has a coefficient of friction that is at least about 12% less than the coefficient of friction of an elastomeric substrate that is not coated with the polymeric coating.

6. The article of manufacture of claim 1, wherein the elastomeric substrate has an associated transmission of water vapor or gases that is at least about 20% less than the transmission of water vapor or gases associated with an elastomeric substrate that is not coated with the polymeric coating tested under substantially the same conditions of pressure, temperature and time.

7. The article of manufacture of claim 1, wherein the polymeric coating has a thickness between about 50 Å and about 5 micrometers.

8. The article of manufacture of claim 1, wherein either of M¹ or M² is titanium.

9. The article of manufacture of claim 1, wherein the polymeric coating is essentially free of silicone oil.

10. The article of manufacture according to claim 1, wherein said polymeric coating is bonded to said substrate.

11. The article of manufacture according to claim 1, further comprising a lubricious hydrophobic layer present on said polymeric coating.

12. The article of manufacture according to claim 11, wherein said lubricious hydrophobic layer is formed from a hydrophobic organic lubricant selected from the group consisting of fluorocarbons, fatty acids, and fatty acid esters.

13. A pharmaceutical closure for a drug vial comprising:
a closure member having an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M²is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the total residue extracted by a volume of water contacted with the polymeric coating is reduced by at least about 20% compared to the total residue extracted by an equivalent volume of water contacted with an elastomeric substrate that is not coated with the polymeric coating under substantially the same conditions of pressure and temperature.

14. A pharmaceutical closure of claim 13, wherein the elastomeric substrate has a coefficient of friction that is at least about 12% less than the coefficient of friction of an elastomeric substrate that is not coated with the polymeric coating.

15. A hypodermic syringe stopper comprising:
a stopper having an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M²is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the total residue extracted by a volume of water contacted with the polymeric coating is reduced by at least about 20% compared to the total residue extracted by an equivalent volume of water contacted with an elastomeric substrate that is not coated with the polymeric coating under substantially the same conditions of pressure and temperature.

16. A hypodermic syringe stopper according to claim 15, wherein the elastomeric substrate has a coefficient of friction that is at least about 12% less than the coefficient of friction of an elastomeric substrate that is not coated with the polymeric coating.

17. A gasket comprising:
a gasket member having an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the total residue extracted by a volume of water contacted with the polymeric coating is reduced by at least about 20% compared to the total residue extracted by an equivalent volume of water contacted with an elastomeric substrate that is not coated with the polymeric coating under substantially the same conditions of pressure and temperature.

18. The gasket of claim 17, wherein the gasket member comprises an o-ring.

19. The gasket of claim 17, wherein the gasket member is configured to be incorporated into an inhaler for delivering a pharmaceutical compound to a mammal in need of treatment.

20. The gasket of claim 17, wherein the elastomeric substrate has a coefficient of friction that is at least about 12% less than the coefficient of friction of an elastomeric substrate that is not coated with the polymeric coating.

21. The gasket of claim 17, wherein the elastomeric substrate has an associated transmission of water vapor or gases that is at least about 20% less than the transmission of water vapor or gases associated with an elastomeric substrate that is not coated with the polymeric coating tested under substantially the same conditions of pressure, temperature and time.

22. A seal comprising:
a sealing member having an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the swelling of the elastomer substrate exposed to a solvent is reduced by at least about 20% compared to the swelling of an elastomeric substrate that is not coated with the polymeric coating exposed to the solvent under substantially the same conditions of pressure and temperature.

23. A seal according to claim 22, wherein the elastomeric substrate has a coefficient of friction that is at least about 12% less than the coefficient of friction of an elastomeric substrate that is not coated with the polymeric coating.

24. A seal according to claim 22, wherein the elastomeric substrate has an associated transmission of water vapor or gases that is at least about 20% less than the transmission of water vapor or gases associated with an elastomeric substrate that is not coated with the polymeric coating tested under substantially the same conditions of pressure, temperature and time.

25. A pharmaceutical delivery device comprising:
a drug container comprising:
a barrel for containing a pharmaceutical substance;
a movable stopper situated within the barrel; and
a blunt end having an opening through which the substance within the barrel can be expelled;
wherein the stopper comprises:
an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the total extractable residue of a volume of water contacted with the polymeric coating is reduced by at least about 20% compared to the total extractable residue of the same volume of water contacted with an elastomeric substrate that is not coated with the polymeric coating under substantially the same conditions of pressure and temperature.

26. The pharmaceutical delivery device of claim 25, wherein the elastomeric substrate has a coefficient of friction that is at least about 12% less than the coefficient of friction of an elastomeric substrate that is not coated with the polymeric coating.

27. The pharmaceutical delivery device of claim 25, wherein the drug container comprises a syringe.

28. The pharmaceutical delivery device of claim 25, wherein the pharmaceutical delivery device is essentially free of silicone oil.

29. A vial for storing medicament comprising:
a container comprising an open end with a radial rim portion surrounding the open end; and
a stopper comprising a tubular portion inserted into the open end of the container and a generally planar rim portion which overlies the radial rim portion;
wherein the stopper comprises:
an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M²or C must be present and at least one of C, H, O, or N must be present in said polymeric coating, except that M² and H may not be exclusively present;
wherein the total residue extracted by a volume of water contacted with the polymeric coating is reduced by at least about 20% compared to the total residue extracted by an equivalent volume of water contacted with an elastomeric substrate that is not coated with the polymeric coating under substantially the same conditions of pressure and temperature.

30. A vial according to claim 29, wherein the elastomeric substrate has a coefficient of friction that is at least about 12% less than the coefficient of friction of an elastomeric substrate that is not coated with the polymeric coating.

31. A vial according to claim 29, wherein the stopper is essentially free of silicone oil.

32. A pharmaceutical delivery device comprising:
a drug container comprising:
a container for containing a pharmaceutical substance and a propellant at a pressure greater than atmospheric pressure for delivering the pharmaceutical substance;
a valve operatively connected to the container for dispensing a controlled dose of the propellant and pharmaceutical substance;
wherein the valve comprises at least one seal comprising:
an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M²is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the total residue extracted by a volume of water contacted with the polymeric coating is reduced by at least about 20% compared to the total residue extracted by an equivalent volume of water contacted with an elastomeric substrate that is not coated with the polymeric coating under substantially the same conditions of pressure and temperature.

33. The pharmaceutical delivery device of claim 32, wherein the drug container comprises a nasal spray.

34. The pharmaceutical delivery device of claim 32, wherein the drug container comprises an inhaler.

35. The pharmaceutical delivery device of claim 32, wherein the valve is essentially free of silicone oil.

36. The pharmaceutical delivery device of claim 32, wherein the elastomeric substrate has a coefficient of friction that is at least about 12% less than the coefficient of friction of an elastomeric substrate that is not coated with the polymeric coating.

37. The pharmaceutical delivery device of claim 32, wherein the elastomeric substrate has an associated transmission of water vapor or gases that is at least about 20% less than the transmission of water vapor or gases associated with an elastomeric substrate that is not coated with the polymeric coating tested under substantially the same conditions of pressure, temperature and time.

38. A vacuum seal comprising:
a first closure member having an opening;
a second closure member sized to cover the opening; and
a sealing member for forming a connection seal between the first closure member and the second closure member, wherein the sealing member comprises:
an elastomeric substrate; and
a plasma deposited polymeric coating on a portion of the elastomeric substrate, wherein the polymeric coating comprises:
a crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating, except that M² and H may not be exclusively present;
wherein the elastomeric substrate has an associated transmission of water vapor or gases that is at least about 20% less than the transmission of water vapor or gases associated with an elastomeric substrate that is not coated with the polymeric coating tested under substantially the same conditions of pressure, temperature and time.

39. The vacuum seal of claim 38, wherein the sealing member comprises an o-ring.

40. The vacuum seal of claim 38, wherein the coating is essentially free of silicone oil.

41. The vacuum seal of claim 38, wherein the elastomeric substrate has a coefficient of friction that is at least about 12% less than the coefficient of friction of an elastomeric substrate that is not coated with the polymeric coating.

42. A method of forming a crosslinked amorphous polymer, said method comprising:
exposing a composition comprising at least one metal organic precursor to an energy source to form a energized precursor;
promoting the energized precursor into an excited state to produce ionized materials; and
depositing the ionized materials on a substrate such that the ionized materials form the crosslinked amorphous polymer represented by a formula selected from the group consisting of:
(1) M¹ₓC_{y}H_{z}OₐN_{b}
wherein M¹ is a metal selected from the group consisting of titanium, silicon, tantalum, germanium, boron, zirconium, aluminum, hafnium, and yttrium, wherein x ranges from 0 to 1, y ranges from 0 to 12, z ranges from 0 to 28, a ranges from 0 to 4, and b ranges from 0 to 4, subject to the proviso that at least one of M¹ or C must be present and at least one of C, H, O, or N must be present in said polymeric coating composition, except that M¹ and H may not be exclusively present; and
(2) M²_{c}C_{d}HₑO_{f}N_{g}
wherein M² is a metal selected from the group consisting of titanium, tantalum, germanium, boron, zirconium, aluminum, hafnium, and yttrium, wherein c ranges from 0 to 1, d ranges from 0 to 12, e ranges from 0 to 28; f ranges from 0 to 4, and g ranges from 0 to 4, subject to the proviso that at least one of M² or C must be present and at least one of C, H, O, or N must be present in said polymeric coating composition, except that M² and H may not be exclusively present.

43. The method according to claim 42, wherein either of M¹ or M² is titanium.

44. The method according to claim 42, wherein the metal organic precursor is a monomer selected from the group consisting of silanes, siloxanes, silazanes,titanates, and mixures thereof.

45. The method according to claim 42, wherein the metal organic precursor comprises tetramethysilane.

46. The method according to claim 42, wherein the metal organic precursor comprises tetraisopropyl titaniate.

47. The method according to claim 42, wherein said step of promoting the energized precursor into an excited state to produce ionized materials comprises breaking down the monomer into atomic species, molecular species, or both.

48. The method according to claim 42, wherein said method is a plasma enhanced chemical vapor deposition method.

49. The method according to claim 42 further comprising:
adding a lubricous coating layer comprising a hydrophobic or hydrophilic organic lubricant selected from the group consisting of fluorocarbons, fatty acids, and fatty acid esters.

50. The method according to claim 49, wherein said lubricious coating layer is applied by one or more of dip, spray, or flow coating techniques.
